(19) United States
(12) Patent Application Publication
(10) Pub. No.: US 2025/0022718 A1
(43) Pub. Date: Jan. 16, 2025

(54) ETCHING METHOD FOR SEMICONDUCTOR STRUCTURE COMPRISING SUBSTRATE, FIRST STRUCTURE LOCATED ON PART OF TOP SURFACE OF THE SUBSTRATE, SIDEWALLS STRUCTURE AND FIELD EFFECT TRANSISTOR

(71) Applicant: Silergy Semiconductor Technology (Hangzhou) LTD, Hangzhou (CN)

(72) Inventor: Huan Wang, Hangzhou (CN)

(21) Appl. No.: 18/747,608

(22) Filed: Jun. 19, 2024

(30) Foreign Application Priority Data
Jul. 11, 2023 (CN) 202310848834.7

(51) Int. Cl. H01L 21/311; H01L 29/51; H01L 29/66; H01L 29/78

(52) U.S. Cl. CPC H01L 21/31116; H01L 21/31111; H01L 29/511; H01L 29/6656; H01L 29/66681; H01L 29/7816

(57) ABSTRACT

A method of etching for a semiconductor structure having a substrate, and a first structure located on part of a top surface of the substrate, where two side surfaces of the first structure are configured as sidewalls, can include: forming an insulation layer to cover the substrate, the first structure, and the sidewalls; performing a dry etching process to etch a first portion of the insulation layer; and performing a wet etching process to etch a remaining portion of the insulation layer, in order to expose the top surface of the substrate, where a thickness of the first portion of the insulation layer etched by the dry etching process is greater than a thickness of the remaining portion of insulation layer etched by the wet etching process, in order to decrease formation of cavity in the substrate and/or sidewalls.

### RELATED APPLICATIONS

This application claims the benefit of Chinese Patent Application No. 202310848834.7, filed on Jul. 11, 2023, which is incorporated herein by reference in its entirety.

### FIELD OF THE INVENTION

The present invention generally relates to the field of semiconductor technology, and more particularly to etching methods for semiconductor structures.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. Switching power supplies have a wide variety of applications in modern electronics. For example, switching power supplies can be used to drive light-emitting diode (LED) loads. Power switches can be semiconducting devices, including metal-oxide-semiconductor field-effect transistors (MOSFETs) and insulated gate bipolar transistors (IGBTs), among others. For example, laterally-diffused metal-oxide-semiconductor (LDMOS) devices are widely used in such on-off type regulators.

### BRIEF DESCRIPTION OF THE DRAWINGS

FIG. 1 is a cross-sectional view of an example side walls structure with cavities.

FIGS. 2A-2C are cross-sectional views of each stage of an example method of manufacturing a side wall structure, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

Semiconductor devices are generally manufactured using two complex manufacturing processes: front-end manufacturing and back-end manufacturing. Front-end manufacturing may involve the formation of a plurality of die on the surface of a semiconductor wafer. Each die on the wafer may contain active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components can be formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist may be removed, leaving behind a patterned layer. Alternatively, some types of materials can be patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface may be used to produce smaller and more densely packed active and passive components. Planarization can be used to remove material from the surface of the wafer and produce a uniformly flat surface. Planarization can involve polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer may be singulated using a laser cutting tool or saw blade. After singulation, the individual die are mounted to a package substrate that can include pins or contact pads for interconnection with other system components. Contact pads formed over the semiconductor die can then be connected to contact pads within the package. The electrical connections can be made with solder bumps, stud bumps, conductive paste, or wire bonds, as a few examples. An encapsulant or other molding material may be deposited over the package to provide physical support and electrical isolation. The finished package can then be inserted into an electrical system and the functionality of the semiconductor device is made available to the other system components.

The manufacturing process of semiconductor integrated circuits mainly can include the formation of devices such as transistors in the active region of the surface of the semiconductor substrate. These devices need to be isolated from each other through isolation structures. Both trench isolation structure and field oxide isolation structure are often used to isolate the active region of semiconductor substrate.

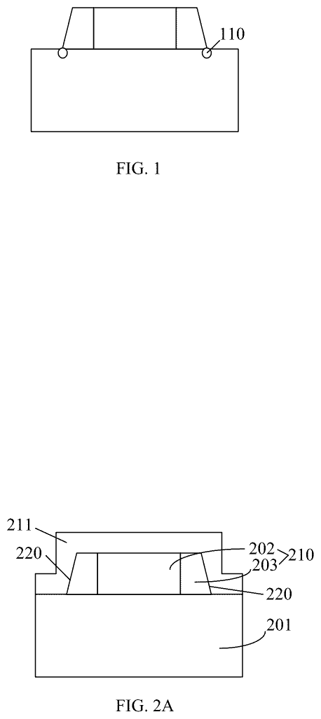

Referring now to FIG. 1, shown is a cross-sectional view of an example side walls structure with cavities. In complementary metal-oxide-semiconductor (CMOS) and laterally-diffused metal-oxide-semiconductor (LDMOS) processes, the steps of forming metal salicides can include: forming polycrystalline silicon and spacers on a silicon substrate; depositing a metal salicide block (SAB) layer on the polycrystalline silicon and spacers; exposing and defining an SAB region; wet etching the SAB layer; and forming metal salicides. However, as shown in FIG. 1, due to the isotropy of wet etching, a portion of the substrate or the spacers may also be removed in the horizontal direction to form cavities 110 on the junction between the spacers and the substrate.

In particular embodiments, a method for reducing the formation of voids on the sidewalls when etching the insulation layer on both sides of the sidewalls, where the sidewalls are configured as both sides of a first structure located on a substrate, and an insulation layer is located on both sides of the sidewalls, can include: performing a dry etching process to etch a first portion of the insulation layer; and performing a wet etching process to etch a remaining portion of insulation layer to expose an upper surface of the substrate, where a thickness of the first portion of the insulation layer etched by the dry etching process is greater than a thickness of the remaining portion of insulation layer etched by the wet etching process, and the surface topography of the sidewalls remains essentially unchanged after the step of performing the wet etching process.

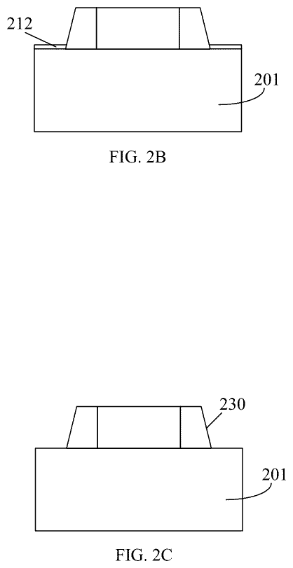

Referring now to FIGS. 2A-2C, shown are cross-sectional views of each stage of an example method of manufacturing a side wall structure, in accordance with embodiments of the present invention. In FIG. 2A, structure 210 can be located on substrate 201, and insulation layer 211 may be formed on both sides of structure 210. Also, side walls 220 can be configured as both side surfaces of structure 210. For example, side walls 220 can be perpendicular to an upper surface of substrate 201, and side walls 220 may also be an oblique side. In addition, an obtuse angle can be formed between side walls 220 and substrate 201.

In particular embodiments, structure 210 can be configured as a gate structure of the device. For example, the gate structure may include a gate oxide layer located on a top surface of substrate 201, and gate conductor 202 located on the gate oxide layer. The gate structure can also include spacers 203 located on both sides of gate conductor 202. For example, insulation layer 211 may be configured as a metal salicide block (SAB) layer, which can be located on both sides of structure 210 and a top surface of structure 210. The method can also include an exposure process and defining of the SAB region. That is, the photoresist can be retained on the SAB layer above the region that does not need to form the metal salicide, and the etching process can be performed to remove the SAB layer above the region that needs to form the metal salicide. In other examples, insulation layer 211 may be configured as other insulation structures that may need to be removed.

For example, the total thickness of the insulation layer can be from about 300 angstroms to about 800 angstroms. Also for example, the material of the insulation layer can be configured as one of SiO₂ material, or two layers of material SiO₂ and SiN, or three layers of material SiO₂, SiN, and SiO₂. In other examples, the first structure (e.g., 210) can be configured as another structure, as long as the method of removing the insulation layer on both sides of the first structure is utilized to prevent the formation of cavities on the side walls of the first structure during the process of removing the insulation layer.

As shown in FIG. 2B, insulation layer 211 can be partially etched using a dry etching process. In this step, the dry etching process may be performed to etch as much insulation layer as possible, and less insulation layer 212 can be retained on the top surface of substrate 201, such that a thickness of the remaining insulation layer 212 is, e.g., less than or equal to 100 angstroms. The dry etching process can be selected, such as ion milling etching, plasma etching, reactive ion etching, laser ablation, etc., and an etched thickness of the insulation layer may be controlled by setting the dry etching time and etching rate.

As shown in FIG. 2C, the remaining insulation layer can be etched using a wet etching process, in order to expose the top surface of the substrate. For example, the wet etching process may be configured as isotropic etching to etch the remaining insulation layer. A thickness of the insulation layer removed by the dry etching process, e.g., can be greater than a thickness of the insulation layer removed by the wet etching process to decrease formation of cavity in the substrate and/or sidewalls. Also, the surface topography of the sidewalls may remain essentially unchanged after the wet etching process is completed.

In particular embodiments, in order to reduce the cavities in the sidewalls and substrate, and particularly the cavities at the junction between the sidewalls and the substrate, the thickness of the insulation layer etched by the wet etching process can be controlled to be, e.g., not greater than 100 angstroms. Further, the thickness of the insulation layer etched by the wet etching process can be controlled to be, e.g., not less than 25 angstroms.

In particular embodiments, the solution used for wet etching process (e.g., hydrofluoric acid), and the formation of cavities at the junction of the upper surface of the substrate and the sidewalls, may be controlled by controlling the time of the wet etching process. Also for example, the insulation layer can be configured as oxide(s), and other solutions that remove oxides can also be used, such as buffered oxide etch (BOE), which has high selectivity for oxides. The BOE can include hydrofluoric acid (e.g., 49%) mixed with water or ammonium fluoride mixed with water.

In particular embodiments, the first structure (e.g., 210) can be applied to the gate structure in MOS devices. Also, before the step of etching insulation layer 211, a photolithography exposure process can be included to define the SAB region. That is, the photoresist can be retained on the SAB layer above the region that does not need to form the metal salicide, and the etching process can be performed to remove the SAB layer above the region that needs to form the metal salicide. After removing the SAB layer using the etching process of particular embodiments, relatively few or even no cavities may be formed at the sidewalls and the substrate. Further, metal salicide can be formed on the first structure, which can improve the performance of the device.

As shown in FIG. 2C, a sidewalls structure can be formed using the method of certain embodiments. The surface topography of sidewalls 230 can be flat, and there may be few or even no cavities, particularly at the junction of sidewalls 230 and substrate 201, where there are essentially no cavities.

In particular embodiments, a field-effect transistor (FET) can include a substrate, a gate structure located on part of a top surface of the substrate, and a sidewalls structure, where two side surfaces of the gate structure can be configured as the sidewalls structure, and a surface of the substrate and/or surfaces of sidewalls may include few or no cavities.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A method of etching for a semiconductor structure having a substrate, and a first structure located on part of a top surface of the substrate, wherein two side surfaces of the first structure are configured as sidewalls, the method comprising:
a) forming an insulation layer to cover the substrate, the first structure, and the sidewalls;
b) performing a dry etching process to etch a first portion of the insulation layer; and
c) performing a wet etching process to etch a remaining portion of the insulation layer, in order to expose the top surface of the substrate,
d) wherein a thickness of the first portion of the insulation layer etched by the dry etching process is greater than a thickness of the remaining portion of insulation layer etched by the wet etching process, in order to decrease formation of cavity in the substrate and/or sidewalls.

2. The method of claim 1, wherein the thickness of the remaining portion of the insulation layer etched by the wet etching process is not greater than 100 angstroms.

3. The method of claim 1, wherein the thickness of the remaining portion of the insulation layer etched by the wet etching process is not less than 25 angstroms.

4. The method of claim 1, wherein a surface of the substrate and/or a surface of sidewalls comprises few cavities or no cavities.

5. The method of claim 1, wherein a total thickness of the insulation layer is from 300 angstroms to 800 angstroms.

6. The method of claim 1, wherein the insulation layer comprises SiO₂ material.

7. The method of claim 1, wherein the insulation layer comprises two layers of material SiO₂ and SiN.

8. The method of claim 1, wherein the insulation layer comprises three layers of material SiO₂, SiN, and SiO₂.

9. The method of claim 1, wherein the wet etching process comprises isotropic etching.

10. The method of claim 1, wherein the first structure is configured as a gate structure having a gate oxide layer located on an upper surface of the substrate, and a gate conductor located on the gate oxide layer.

11. The method of claim 1, wherein the gate structure further comprises spacer layers located on both sides of the gate conductor.

12. The method of claim 1, wherein the insulation layer comprises a metal salicide block layer.

13. A sidewalls structure, formed by the method of claim 1, wherein the sidewalls structure comprises two sides of the first structure located on the substrate, and wherein the top surface of the substrate and/or surfaces of sidewalls comprises few cavities or no cavities.

14. A field-effect transistor, comprising the sidewalls structure of claim 13, and further comprising:
a) the substrate; and
b) a gate structure located on part of a top surface of the substrate,
c) wherein two side surfaces of the gate structure are configured as the sidewalls structure, and a surface of the substrate and/or surfaces of sidewalls comprises few cavities or no cavities.
